(19) United States
(12) Patent Application Publication
(10) Pub. No.: US 2009/0252041 A1
(43) Pub. Date: Oct. 8, 2009

(54) Optimized statistics processing in integrated DPI service-oriented router deployments

(75) Inventors: Andrew Dolganow, Kanata (CA); Steven Edwad Morin, Ottawa (CA)

Correspondence Address: Kramer & Amado, P.C., 1725 Duke Street, Suite 240, Alexandria, VA, 22314, US

(73) Assignee: ALCATEL LUCENT, Paris (FR)

(21) Appl. No.: 12/078,700

(22) Filed: Apr. 3, 2008

(51) Int. Cl. G01R 31/08

(52) U.S. Cl. 370/241

(57) ABSTRACT

A method of processing statistics in integrated deep packet inspection routers, including one or more of the following: getting a first entity, determining that an application statistic has changed for the first entity, getting application statistics for a first application of the first entity, determining that the application statistics for the first application of the first entity have changed, and processing the application statistics for the first application of the first entity.

### BACKGROUND OF THE INVENTION

1. Field of the Invention

This invention relates generally to packet based communications using deep packet inspection (DPI).

2. Description of Related Art

In its existing form, DPI is a sort of computer network packet processing that examines data and/or header part of a packet as it passes an inspection point, searching for non-protocol compliance, viruses, spam, intrusions or predefined criteria defining a protocol or application to decide what if any content specific processing needs to be performed. DPI is also sometimes called Content Inspection or Content Processing. DPI is in contrast to shallow packet inspection (usually called just packet inspection) which just checks the lower-layer header portion of a packet (usually up to Layer 3 of the OSI model).

DPI devices have the ability to look at Layer 2 through Layer 7 of the OSI model. This includes headers and data protocol structures as well as the actual payload of the message. The DPI will identify and classify the traffic based on a signature database and the information extracted from the packet, allowing finer control than classification based only on header information.

A classified packet can be, among others, redirected, marked/tagged (see QoS), blocked, rate limited, and of course reported to a reporting agent in the network. DPI devices first identify packet DPI flows (for example defined by IP 5-tuple) and then perform DPI on packets within each flow, allowing identification and control actions based on accumulated single or multiple flow information.

DPI allows phone and cable companies to readily know the type of applications a user is receiving online, from e-mail, to websites, to sharing of music, video and software downloads as would a network analysis tool. This is the approach that cable operators and ISPs may use, for example, to dynamically allocate bandwidth resources to match requirements of a particular application that is passing through their networks. Thus, for example, a low-latency resources can be allocated to a VoIP call versus web browsing.

DPI is also increasingly being used in security devices to analyze flows, compare them against policy, and then treat the traffic appropriately (i.e., block, allow, rate limit, tag for priority, mirror to another device for more analysis or reporting). Since the DPI device looks at each individual packet, it can be used by ISPs to provide or block services on a user by user basis.

A variety of approaches to data filtering are also known. When working with a small amount of data it is often adequate to process the entire quantity of the data. However, when the size of a set of data is sufficiently large, performance problems can begin to occur when attempting to process all of the data.

Further, in addition to processing delays caused by processing the entire quantity of data in a data set, the usability of the processed data also becomes an issue. Accordingly, the purpose of data filtering is to assist a user in isolating desired information from irrelevant information. This also results in an increase in processing speed.

The foregoing objects and advantages of the invention are illustrative of those that can be achieved by the various exemplary embodiments and are not intended to be exhaustive or limiting of the possible advantages which can be realized. Thus, these and other objects and advantages of the various exemplary embodiments will be apparent from the description herein or can be learned from practicing the various exemplary embodiments, both as embodied herein or as modified in view of any variation that may be apparent to those skilled in the art. Accordingly, the present invention resides in the novel methods, arrangements, combinations, and improvements herein shown and described in various exemplary embodiments.

### SUMMARY OF THE INVENTION

In light of the present need for optimized statistics processing in integrated DPI service-oriented router deployments, a brief summary of various exemplary embodiments is presented. Some simplifications and omissions may be made in the following summary, which is intended to highlight and introduce some aspects of the various exemplary embodiments, but not to limit the scope of the invention. Detailed descriptions of a preferred exemplary embodiment adequate to allow those of ordinary skill in the art to make and use the inventive concepts will follow in later sections.

DPI technology is evolving from standalone, dedicated DPI equipment often deployed off-line to include integrated, in-line systems. An example of an integrated DPI deployment is a router with an integrated DPI functionality. Such a deployment produces many challenges to existing routers as integrated functionality usually means hardware and/or software resources are shared for DPI functionality and non-DPI functionality.

Further, DPI systems commonly have issues with producing too many statistics especially when a subscriber-scope for those statistics is desired. Hundreds of thousands of subscribers or more and thousands of protocols and applications that a single DPI network element may see produces amounts of statistics that are hard to use or scale. The foregoing problems become especially visible in subscriber-aware routers with integrated DPI, as the number of subscribers an application-aware subscriber edge router is to support produces an extreme tax on the router's hardware and software resources.

Although dedicated DPI service blade hardware is a common choice for integrated application-aware routers, the router still typically needs to deal on a system level with many application-aware subscribers. One significant related issue is the amount of statistics a router can generate for an application-aware subscriber. Even a moderately scaled router often supports on an order of tens of thousands of subscribers each with hundreds or more of application specific records, and each of them with tens of statistics.

Processing such a volume of data on a router, such that the statistics can be exported reliably for processing in a related system on a network-level, results in a massive tax on the equipment, statistics traffic volume, and network database required for statistics processing. Accordingly, various exemplary embodiments reduce the amount of statistical data router and higher layers process.

When an application-aware router is deployed in a converged environment, servicing more than one type of subscriber, such as a business and an individual mobile user, many applications may need to be defined based on subscriber type and service type. Although described herein in connection with one exemplary embodiment, this problem is common to any DPI equipment. Thus, it should be apparent that the solutions to the problem described herein are applied to any type of DPI equipment in various exemplary embodiments.

As introduced above, certain forms of DPI equipment allow the definition of a thousand or more applications based on hundreds of protocol signatures. Defining so many applications for a router introduces scaling limitations, especially when related to statistics operators want to collect for each application. Being unable to deal with per-application, per-subscriber statistics volume, certain DPI equipment only report application statistics on a system level while allowing per-subscriber statistics on a limited number of subscribers. One such implementation allows per-subscriber statistics for only hundreds of subscribers whereas a need is believed to exist to support 128,000 subscribers or more. Another implementation significantly reduces the total number of subscribers a DPI network element can handle while subscriber-level application/protocol statistics are to be collected and processed. Yet another implementation relies on interval based statistics with an interval time long enough to process all per-subscriber per-application and protocol statistics and statistics shedding for exception handling (tail dropping records when processing cannot be completed within an interval).

This produces a problem to operators who are focused on collecting and processing per-application, per-subscriber statistics in the intervals adequate to, for example, deploy application-aware per-subscriber services. Accordingly, various exemplary embodiments enable the processing of per-application, per-subscriber statistics, when the processing may include any one of, or any combination of, allocating statistics resources, incrementing statistics, collecting and processing statistics, and exporting statistics to an external device for further processing.

Various exemplary embodiments combine the properties of data filtering with application-aware subscriber statistics. Accordingly, various exemplary embodiments define an application statistic filter that enables an operator to define which DPI-recognizable application, protocols, and so on, have their statistics processed by a router.

In various exemplary embodiments, the filter allows an operator to differentiate statistics processing inside a DPI engine on a per-subscriber, subscriber-type level, even when the DPI engine services all types of subscribers and all type of protocols, applications and so on. In various exemplary embodiments, a router processes application-aware statistics only for a subset of applications, protocols, or combination thereof, and so on, per subscriber. Accordingly, various exemplary embodiments enable an operator to process application-aware statistics per each subscriber for a subset of applications while at the same time enabling monitoring of all statistics by dynamically changing application filters to take per interval samples.

Various exemplary embodiments are used for other statistics manipulation, such as linking some of the statistic reducing methods with an observation to a nature of application-aware statistics. It is observed that, for an application-aware subscriber router, only a subset of subscribers is active at a given statistic collection interval. In various exemplary embodiments, a few-fold reduction is achieved by processing only active subscriber data.

Moreover, the active subscribers are believed to be extremely unlikely to run all of the hundreds of applications that are being tracked, identified, and processed. Thus, on average at least an order of magnitude reduction in applications is achieved by various exemplary embodiments when processing specifies inclusion of only statistics that have changed. The scale of savings increases as the sophistication of DPI-service increases, because more applications are identified and used in a service offering. This is a trend believed to be present in the commercial marketplace today.

Various exemplary embodiments, incorporating the foregoing, achieve an order of magnitude savings of two in data processing on a router and network level. Accordingly, various exemplary embodiments only process application data for active subscribers application records that changed in the statistics interval being reported upon. Thus, various exemplary embodiments enable scaled DPI integration into existing routers.

### BRIEF DESCRIPTION OF THE DRAWINGS

In order to better understand various exemplary embodiments, reference is made to the accompanying drawings, wherein:

FIG. 1 is a flowchart of an exemplary embodiment of a method of optimization statistics processing in integrated DPI service-oriented router deployments; and

FIG. 2 is a flowchart of an exemplary embodiment of a method of using a statistics filter for optimization statistics processing in integrated DPI service-oriented router deployments.

### DETAILED DESCRIPTION OF THE PREFERRED EMBODIMENTS OF THE INVENTION

Referring now to the drawings, in which like numerals refer to like components or steps, there are disclosed broad aspects of various exemplary embodiments.

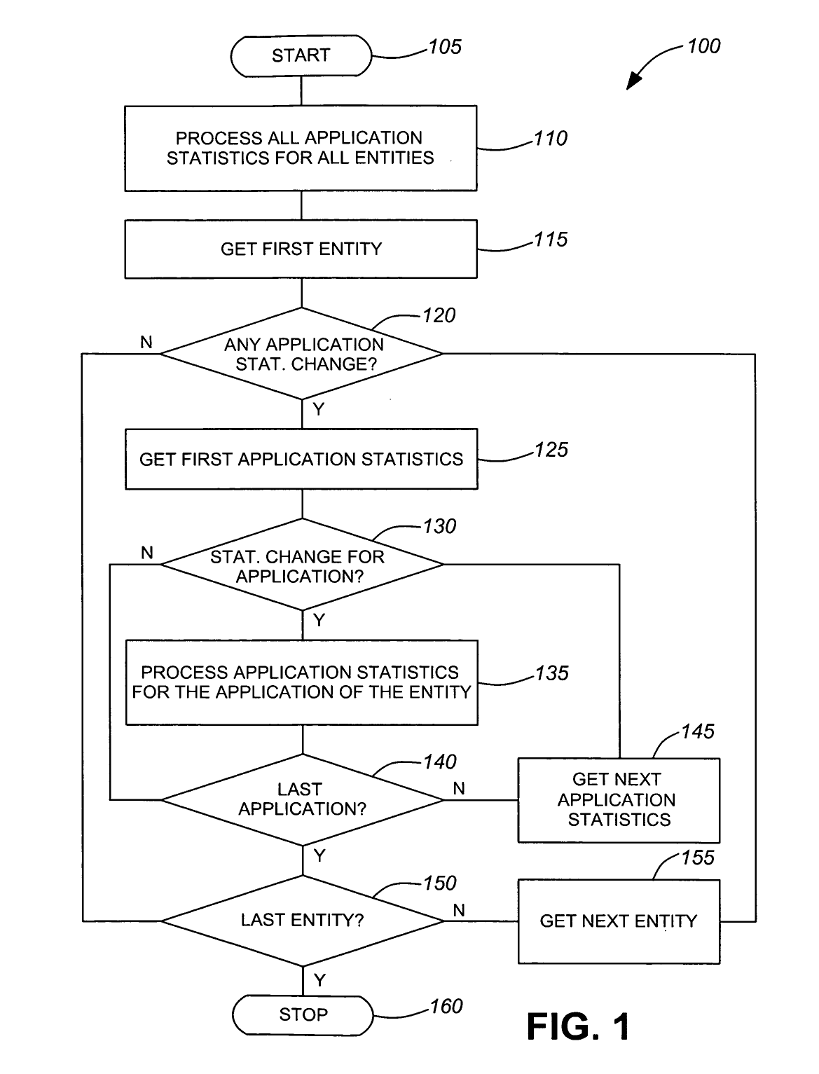

FIG. 1 is a flowchart of an exemplary embodiment of a method 100 of optimization statistics processing in integrated DPI service-oriented router deployments. The method 100 starts in step 105, and continues to step 110.

In step 110, processing begins on all application statistics for all entities. In various exemplary embodiments, step 110 includes the act of collecting the statistics. In other exemplary embodiments, step 110 includes processing of previously collected statistics. It should be apparent that other variations and combinations exist regarding the collection of the statistics processed in step 110.

In step 115, the method gets a first entity. Examples of the entities include a subscriber, an end user, the equipment of a subscriber or end user, and a group of subscribers or end users, including those attached to a common access device such as a DSLAM, router, Ethernet switch, BRAS, a network, and so on. It should be apparent that any type of entity currently known, or later developed, not limited to the examples given herein, can be the entity of step 115.

In step 120, a determination is made with respect to the first entity of step 1 15 whether any statistic has changed for any application. Examples of applications include a protocol used to send data, such as TCP, HTTP, and so on, an application that uses a protocol, such as video, VoIP, a game, and so on, including any grouping of applications such as, for example, a themed grouping of applications such as gaming applications. In various exemplary embodiments, in connection with step 120, the DPI recognizes and classifies traffic into associated applications.

When a determination is made in step 120 that no statistic has changed for any application of the first entity, the method 100 proceeds to step 150. When a determination is made in step 120 that at least some statistic has changed for at least one application of the first entity, the method 100, proceeds to step 125.

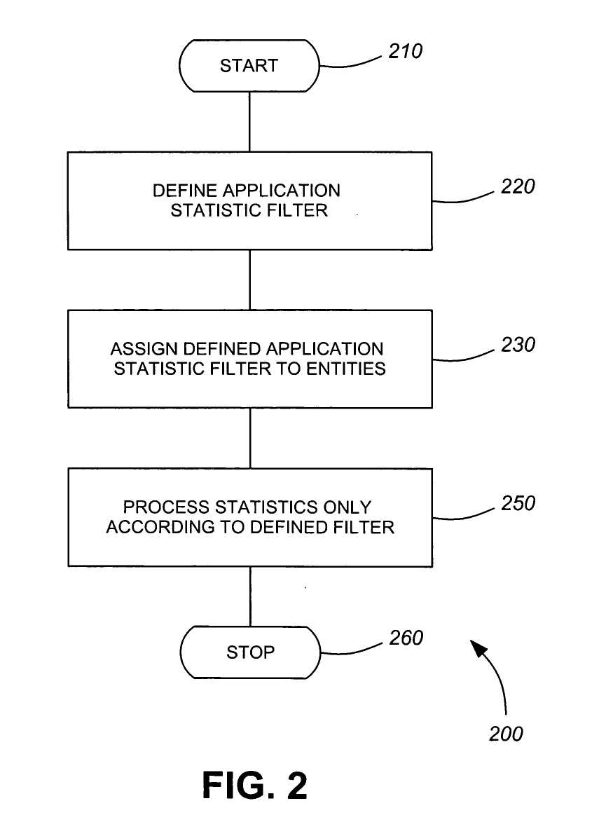

In step 125, statistics are obtained for a first application. This will be discussed in greater detail in connection with FIG. 2.

In step 130, a determination is made whether any of the first application statistics of step 125 have changed. When a determination is made in step 130 that none of the first application statistics of step 125 have changed, the method 100 proceeds to step 140. This will be discussed more below.

When a determination is made in step 130 that at least some of the first application statistics of step 125 have changed, the method 100 proceeds to step 135. In step 135, the application statistics for the application of the entity are processed. In various exemplary embodiments, step 135 includes processing a regular output record, processing a cumulative output record, sending a record, writing a copy of a record, modifying a record, and so on. This will be discussed in greater detail in connection with FIG. 2.

In step 140, a determination is made whether the application for which step 130 and step 135 were just performed is the last application. When a determination is made in step 140 that the application for which step 130 and step 135 were just performed is not the last application, the method 100 proceeds to step 145. In step 145, the method gets the statistics for the next application. This is similar to step 125 described above, except that the application statistics of step 145 are not the first application statistics, and the application statistics of step 125 are the first application statistics.

Following step 145, the method 100 returns to step 130. The method 100 then continues with respect to the next application statistics of step 145 as described above in connection with the first application statistics of step 125.

When a determination is made in step 140 that the application for which step 130 and step 135 were just performed is the last application, the method 100 proceeds to step 150. In step 150, a determination is made whether the entity for which step 120 to step 140 were just performed is the last entity.

When a determination is made in step 150 that the entity for which step 120 to step 140 were just performed is not the last entity, the method 100 proceeds to step 155. In step 155, the method gets the next entity. This is similar to step 115 described above, except that the entity of step 155 is not the first entity, and the entity of step 115 is the first entity.

Following step 155, the method 100 returns to step 120. The method 100 then continues with respect to the next entity of step 155 as described above in connection with the first entity of step 115.

When a determination is made step 150 that the entity for which step 120 to step 140 were just performed is the last entity, the method 100 proceeds to step 160. In step 160, the method 100 stops.

In various exemplary embodiments, the order of the nested loops initiated in exemplary method 100 by step 115 and step 125 is reversed. Accordingly, in various exemplary embodiments, step 115 consists of getting a first application. Then, in step 125, the first entity statistics are obtained for the first application. Then, in step 140, a determination is made whether it is the last entity. Finally, in step 150, a determination is made whether it is the last application. It should be apparent that, in these embodiments, step 120, step 130, step 135, step 140 and step 155 also change accordingly to reverse the order of the nested loops in the method 100.

FIG. 2 is a flowchart of an exemplary embodiment of a method 200 of using a statistics filter for optimization statistics processing in integrated DPI service-oriented router deployments. The method 200 starts in step 210.

In step 220, an application statistics filter is defined. In various exemplary embodiments, a plurality of application statistics filters is defined in step 220.

In various exemplary embodiments, the application statistics filter defined in step 220 selects a subset of all possible protocols, such as HTTP, TCP, Skype, and so on, applications, such as Yahoo, instant messaging, Vonage, VoIP, video, and so on, application groups, such as web browsing, electronic mail, VoIP, and so on. In various exemplary embodiments, the subset of protocols includes protocols that DPI is able to identify.

In step 230, the application statistics filter(s) defined in step 220 are assigned to one or more entities. In various exemplary embodiments, the application statistics filter(s) defined in step 220 are assigned to all of a plurality of entities. In other exemplary embodiments, the application statistics filter(s) defined in step 220 are assigned to a subset of a plurality of entities. In still other exemplary embodiments, a subset of a plurality of application statistics filters defined in step 220 are assigned to a subset of a plurality of entities in step 230.

In step 250, statistics are processed according to the filter(s) defined in step 220. This corresponds to step 135 of exemplary method 100. In various exemplary embodiments, statistics are processed in step 250 only according to the filter(s) defined in step 220. In various exemplary embodiments, only a subset of a plurality of filters defined in step 220 are used for processing statistics in step 250.

In various exemplary embodiments, step 250 includes processing in connection with, and at the time of, any one or combination of the following: record accumulation, record creation, record modification, record storage, record sending, and record post-processing. In various exemplary embodiments the processing of step 250 includes processing on an external device. In various exemplary embodiments, the processing of step 250 includes processing on an internal device. In various exemplary embodiments, the processing of step 250 includes processing on both external and internal devices.

As used herein, it should be understood that processing statistics applies to one or more of various stages of statistics processing. These stages begin with the allocation of resources to internally enable the collection of statistics. A next stage includes collecting or incrementing the statistics internally in the allocated resources as the packets arrive. Another stage includes any manner of storing statistics internally. A final stage includes any manner of forwarding or exporting statistics. In various exemplary embodiments, step 250 includes any one, or any combination of the foregoing stages of statistics processing.

According to the foregoing, various exemplary embodiments enable a commercially viable use of per-subscriber, per application statistics. Likewise, various exemplary embodiments reduce resources, such as RAM and CPU capacity, required to collect, send, and process application-aware subscriber statistics. Similarly, various exemplary embodiments enable increased scaling of subscribers and applications, especially for integrated router solutions.

Although the various exemplary embodiments have been described in detail with particular reference to certain exemplary aspects thereof, it should be understood that the invention is capable of other embodiments and its details are capable of modifications in various obvious respects. As is readily apparent to those skilled in the art, variations and modifications can be affected while remaining within the spirit and scope of the invention. Accordingly, the foregoing disclosure, description, and figures are for illustrative purposes only and do not in any way limit the invention, which is defined only by the claims.

What is claimed is:

1. A method of processing statistics in integrated deep packet inspection routers, comprising:
getting a first entity;
determining that an application statistic has changed for the first entity;
getting application statistics for a first application of the first entity;
determining that the application statistics for the first application of the first entity have changed; and
processing the application statistics for the first application of the first entity.

2. The method of processing statistics in integrated deep packet inspection routers, according to claim 1, further comprising:
determining that the first entity has a next application;
getting application statistics for the next application of the first entity;
determining that the application statistics for the next application of the first entity have changed; and
processing the application statistics for the next application of the first entity.

3. The method of processing statistics in integrated deep packet inspection routers, according to claim 2, further comprising:
determining that there is a next entity;
getting the next entity;
determining that an application statistic has changed for the next entity;
getting application statistics for a first application of the next entity;
determining that the application statistics for the first application of the next entity have changed; and
processing the application statistics for the first application of the next entity.

4. The method of processing statistics in integrated deep packet inspection routers, according to claim 3, further comprising:
determining that the next entity has a next application;
getting application statistics for the next application of the next entity;
determining that the application statistics for the next application of the next entity have changed; and
processing the application statistics for the next application of the next entity.

5. The method of processing statistics in integrated deep packet inspection routers, according to claim 4, wherein:
getting the first entity, determining that the application statistic has changed for the first entity, getting application statistics for the first application of the first entity, determining that the application statistics for the first application of the first entity have changed, and processing the application statistics for the first application of the first entity, occur first;
determining that the first entity has the next application of the first entity, getting application statistics for the next application of the first entity, determining that the application statistics for the next application of the first entity have changed, and processing the application statistics for the next application of the first entity, occur second;
determining that there is the next entity, getting the next entity, determining that the application statistic has changed for the next entity, getting the application statistics for the first application of the next entity, determining that the application statistics for the first application of the next entity have changed, and processing the application statistics for the first application of the next entity, occur third; and
determining that the next entity has the next application, getting application statistics for the next application of the next entity, determining that the application statistics for the next application of the next entity have changed, and processing the application statistics for the next application of the next entity, occur fourth.

6. The method of processing statistics in integrated deep packet inspection routers, according to claim 1, wherein processing the application statistics includes at least one of allocating resources to internally enable collection of the application statistics, incrementing the application statistics internally in allocated resources, storing the application statistics internally, and exporting the application statistics.

7. The method of processing statistics in integrated deep packet inspection routers, according to claim 1, wherein the first entity is selected from the list consisting of a subscriber, an end user, equipment of a subscriber, equipment of an end user, a group of subscribers, a group of end users, equipment of a group of subscribers, and equipment of a group of end users.

8. The method of processing statistics in integrated deep packet inspection routers, according to claim 7, wherein the entity is attached to a common access device.

9. The method of processing statistics in integrated deep packet inspection routers, according to claim 8, wherein the common access device is selected from the list consisting of a DSLAM, a router, an Ethernet switch, a BRAS, and a network.

10. The method of processing statistics in integrated deep packet inspection routers, according to claim 1, wherein the first application of the first entity is selected from the list consisting of a protocol used to send data, application that uses a protocol, and a grouping of applications.

11. The method of processing statistics in integrated deep packet inspection routers, according to claim 10, wherein the first application of the first entity is selected from the list consisting of TCP, HTTP, video, VoIP, a game, a themed group of applications, and a group of gaming applications.

12. The method of processing statistics in integrated deep packet inspection routers, according to claim 1, wherein the processing includes at least one of processing a regular output record, processing a cumulative output record, sending a record, writing a copy of a record, and modifying a record.

13. The method of processing statistics in integrated deep packet inspection routers, according to claim 1, further comprising defining at least one application statistics filter.

14. The method of processing statistics in integrated deep packet inspection routers, according to claim 13, wherein getting application statistics for the first application of the first entity includes applying the at least one application statistics filter.

15. The method of processing statistics in integrated deep packet inspection routers, according to claim 13, wherein processing the application statistics for the first application of the first entity includes applying the at least one application statistics filter.

16. A method of processing statistics in integrated deep packet inspection routers, comprising:
getting a first application, determining that an application statistic has changed for the first application, getting application statistics for a first entity of the first application, determining that the application statistics for the first entity of the first application have changed, and processing the application statistics for the first entity of the first application;
then determining that the first application has a next entity of the first application, getting application statistics for the next entity of the first application, determining that the application statistics for the next entity of the first application have changed, and processing the application statistics for the next entity of the first application;
then determining that there is a next application, getting the next application, determining that an application statistic has changed for the next application, getting application statistics for a first entity of the next application, determining that the application statistics for the first entity of the next application have changed, and processing the application statistics for the first entity of the next application; and
then determining that the next application has a next entity, getting application statistics for the next entity of the next application, determining that the application statistics for the next entity of the next application have changed, and processing the application statistics for the next entity of the next application.

17. A method of processing statistics in integrated deep packet inspection routers, comprising:
defining at least one application statistics filter;
assigning the at least one application statistics filter to at least one entity; and
processing statistics of the at least one entity according to the at least one application statistics filter.

18. The method of processing statistics in integrated deep packet inspection routers, according to claim 17, wherein processing statistics of the at least one entity according to the at least one application statistics filter includes at least one of allocating resources to internally enable collection of the statistics, incrementing the statistics internally in allocated resources, storing the statistics internally, and exporting the statistics.

19. The method of processing statistics in integrated deep packet inspection routers, according to claim 18, wherein statistics are processed only according to the at least one application statistics filter.

20. The method of processing statistics in integrated deep packet inspection routers, according to claim 17, wherein statistics are processed only according to the at least one application statistics filter.

21. The method of processing statistics in integrated deep packet inspection routers, according to claim 17, wherein the application statistics filter selects a subset of all possible protocols, applications, and application groups.

22. The method of processing statistics in integrated deep packet inspection routers, according to claim 21, wherein the application statistics filter selects one or more of HTTP, TCP, Skype, Yahoo, instant messaging, Vonage, VoIP, video, web browsing and electronic mail.

23. The method of processing statistics in integrated deep packet inspection routers, according to claim 17, wherein a plurality of application statistics filters are defined.

24. The method of processing statistics in integrated deep packet inspection routers, according to claim 23, wherein statistics of the at least one entity are processed according to a subset of the plurality of application statistics filters.

25. The method of processing statistics in integrated deep packet inspection routers, according to claim 17, wherein the at least one application statistics filter is assigned to a plurality of entities.

26. The method of processing statistics in integrated deep packet inspection routers, according to claim 17, wherein processing includes processing in connection with, and at a time of, one or more of record accumulation, record creation, record modification, record storage, record sending, and record post-processing.

27. The method of processing statistics in integrated deep packet inspection routers, according to claim 17, wherein processing includes processing on an internal device.

28. The method of processing statistics in integrated deep packet inspection routers, according to claim 17, wherein processing includes processing on an external device.
